(19) United States
(12) Patent Application Publication
(10) Pub. No.: US 2023/0071434 A1
(43) Pub. Date: Mar. 9, 2023

(54) EXTERIOR MATERIAL FOR COOKING APPLIANCE AND MANUFACTURING METHOD THEREOF

(71) Applicant: SAMSUNG ELECTRONICS CO., LTD., Suwon-si (KR)

(72) Inventors: Jiyoung SONG, Suwon-si (KR); Hyunseok SHIN, Suwon-si (KR); Taegyeong KIM, Suwon-si (KR); Youngdeog KOH, Suwon-si (KR); Kwangjoo KIM, Suwon-si (KR); Nohcheol PARK, Suwon-si (KR)

(73) Assignee: SAMSUNG ELECTRONICS CO., LTD., Suwon-si (KR)

(21) Appl. No.: 17/850,442

(22) Filed: Jun. 27, 2022

Related U.S. Application Data
(63) Continuation of application No. PCT/KR2022/008127, filed on Jun. 9, 2022.

(30) Foreign Application Priority Data
Aug. 27, 2021 (KR) 10-2021-0114021
Nov. 1, 2021 (KR) 10-2021-0148310

(51) Int. Cl. A47J 36/04; C23C 14/02; C23C 14/06; C23C 14/22

(52) U.S. Cl. CPC A47J 36/04; C23C 14/022; C23C 14/0605; C23C 14/221

(57) ABSTRACT

An exterior material for cooking appliance capable of improving durability, heat resistance, scratch resistance, and cleaning performance by forming a Silicon-Diamond like carbon (SiDLC) coating layer including silicon (Si) under a high-temperature environment, and a method for manufacturing the exterior material. The exterior material includes: a base material; and a SiDLC coating layer provided on the base material, wherein the SiDLC coating layer includes Si of about 1 weight % to 50 weight %, carbon (C), and other inevitable impurities.

### CROSS-REFERENCE TO RELATED APPLICATION

This application is a continuation application, filed under 35 U.S.C. § 111(a), of International Application PCT/KR2022/008127 filed Jun. 9, 2022, and is based on and claims priority under 35 U.S.C. § 119 to Korean Patent Applications No. 10-2021-0114021, filed on Aug. 27, 2021, and No. 10-2021-0148310, filed on Nov. 1, 2021 in the Korean Intellectual Property Office, the disclosures of which are incorporated by reference herein in their entireties.

### BACKGROUND

### 1. Field

The disclosure relates to an exterior material for cooking appliance and a manufacturing method thereof, and more particularly, to an exterior material for cooking appliance capable of improving durability, heat resistance, scratch resistance, and cleaning performance by forming a Silicon-Diamond like carbon (SiDLC) coating layer including silicon under a high-temperature environment, and a method for manufacturing the exterior material.

### 2. Description of the Related Art

Cooking machines and cooking tools are collectively called cooking appliances, and the cooking appliances are equipment for cooking, reheating, or cooling food, etc. through a heat source, such as a gas, electricity, a steam, etc. Representative cooking appliances include an induction, an oven, a gas range, a microwave, etc.

The exterior material of such a cooking appliance requires certain levels of durability and scratch resistance for protecting the cooking appliance from external impacts. Also, the exterior material of the cooking appliance requires a certain level of heat resistance for preventing the cooking appliance from being damaged by heat entrance and exit. In addition, the exterior material of the cooking appliance requires excellent cleaning performance for creating a sanitary cooking environment.

Accordingly, an exterior material for cooking appliance meeting all of excellent durability, scratch resistance, heat resistance, and cleaning performance urgently needs to be introduced.

### SUMMARY

To overcome the above-described problem, it is an object to the disclosure to provide an exterior material for cooking appliance capable of improving durability, heat resistance, scratch resistance, and cleaning performance by forming a Silicon-Diamond like carbon (SiDLC) coating layer including silicon under a high-temperature environment, and a method for manufacturing the exterior material.

Additional aspects of the disclosure will be set forth in part in the description which follows and, in part, will be obvious from the description, or may be learned by practice of the disclosure.

An exterior material for cooking appliance according to an embodiment of the disclosure includes: a base material; and a Silicon-Diamond like carbon (SiDLC) coating layer provided on the base material, wherein the SiDLC coating layer includes silicon (Si) of 1 weight % to 50 weight %, carbon (C), and other inevitable impurities.

The exterior material according to an embodiment of the disclosure may include ceramic glass.

The exterior material according to an embodiment of the disclosure, a thickness of the base material may be 3 mm to 6 mm.

The exterior material according to an embodiment of the disclosure, Vickers hardness of the SiDLC coating layer may be 1000 Hv to 2000 Hv.

The exterior material according to an embodiment of the disclosure, a vertical force by which a scratch is generated on the SiDLC coating layer may be 15 N to 20 N.

The exterior material according to an embodiment of the disclosure, a friction coefficient of the SiDLC coating layer may be 0.01 to 0.2.

The exterior material according to an embodiment of the disclosure, a chrominance value ΔE of the SiDLC coating layer heated at 300° C. for 480 hours or more may be 1.0 or less.

The exterior material according to an embodiment of the disclosure, a thickness of the SiDLC coating layer may be 1 μm to 4 μm.

A method for manufacturing an exterior material for cooking appliance, according to an embodiment of the disclosure, includes: preparing a base material; etching a surface of the base material; and forming a Silicon-Diamond like carbon (SiDLC) coating layer on the etched base material, wherein the forming of the SiDLC coating layer is performed at 100° C. to 400° C.

In the method for manufacturing the exterior material, according to an embodiment of the disclosure, the etching of the surface of the base material may be performed through Linear Ion Source (LIS) treatment.

In the method for manufacturing the exterior material, according to an embodiment of the disclosure, the forming of the SiDLC coating layer may be performed by a Physical Vapor Deposition (PVD) method.

In the method for manufacturing the exterior material, according to an embodiment of the disclosure, the PVD method may include a Linear Ion Source (LIS) method.

In the method for manufacturing the exterior material, according to an embodiment of the disclosure, the base material may include ceramic glass.

In the method for manufacturing the exterior material, according to an embodiment of the disclosure, a thickness of the base material may be 3 mm to 6 mm.

In the method for manufacturing the exterior material, according to an embodiment of the disclosure, the SiDLC coating layer may include silicon (Si) of 1 weight % to 50 weight %, carbon (C), and other inevitable impurities.

In the method for manufacturing the exterior material, according to an embodiment of the disclosure, a thickness of the SiDLC coating layer may be 1 μm to 4 μm.

A cooking appliance according to an embodiment of the disclosure includes: a cooking appliance body; and an exterior material provided on an outer side of the cooking appliance body, wherein the exterior material includes: a base material; and a Silicon-Diamond like carbon (SiDLC) coating layer provided on the base material, wherein the SiDLC coating layer includes silicon (Si) of 1 weight % to 50 weight %, carbon (C), and other inevitable impurities.

In the cooking appliance according to an embodiment of the disclosure, Vickers hardness of the SiDLC coating layer may be 1000 Hv to 2000 Hv.

In the cooking appliance according to an embodiment of the disclosure, a chrominance value ΔE of the SiDLC coating layer heated at 300° C. for 480 hours or more may be 1.0 or less.

In the cooking appliance according to an embodiment of the disclosure, a thickness of the SiDLC coating layer may be 1 μm to 4 μm.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a schematic view showing an exterior material for cooking appliance according to an embodiment of the disclosure;

FIG. 2 is a schematic flowchart showing a method for manufacturing an exterior material for cooking appliance, according to an embodiment of the disclosure;

FIG. 3 is a graph showing changes of Raman spectrums according to manufacturing process temperature;

FIG. 4 is a picture showing a scratch generation behavior of a comparative example according to a variable load scratch test;

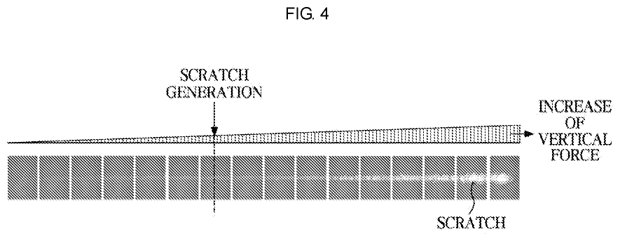

FIG. 5 is a picture showing a scratch generation behavior of an embodiment according to a variable load scratch test;

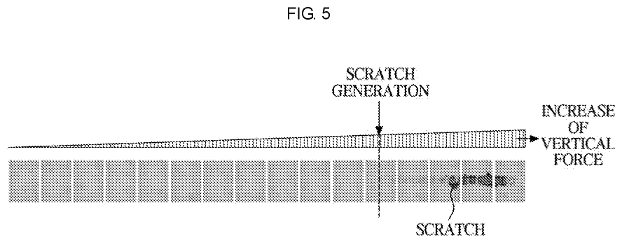

FIG. 6 is a picture obtained by photographing a surface of an exterior material for cooking appliance according to a comparative example through an Atomic Force Microscope (AFM);

FIG. 7 is a picture obtained by photographing a surface of an exterior material for cooking appliance according to an embodiment of the disclosure through an AFM;

FIG. 8 is a graph showing friction coefficients of comparative examples and an embodiment;

FIG. 9 is a picture obtained by photographing an exterior material for cooking appliance according to a comparative example after a blue scrubber scratch test is performed on the exterior material; and

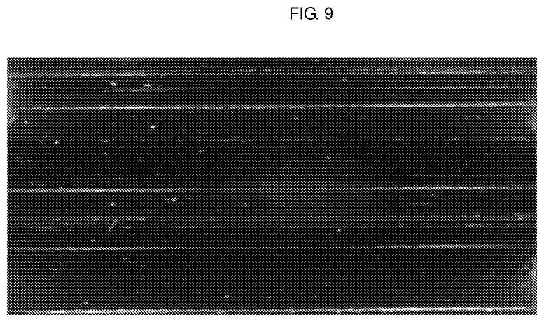

FIG. 10 is a picture obtained by photographing an exterior material for cooking appliance according to an embodiment after a blue scrubber scratch test is performed on the exterior material.

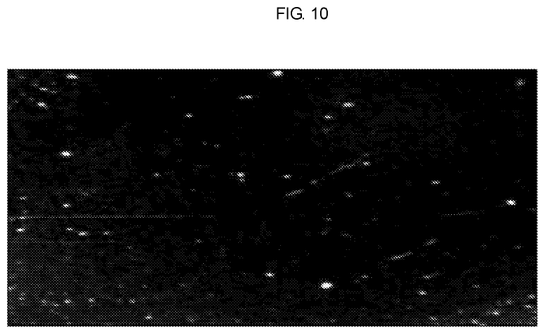

### DETAILED DESCRIPTION

Hereinafter, the embodiments of the disclosure will be described in detail with reference to the accompanying drawings. The following embodiments are provided to sufficiently transfer the concepts of the disclosure to one of ordinary skill in the technical art to which the disclosure belongs. However, the disclosure is not limited to these embodiments, and may be embodied in another form. In the drawings, portions that are irrelevant to the descriptions may be not shown in order to clarify the disclosure, and also, for easy understanding, the sizes of components are more or less exaggeratedly shown.

In the entire specification, it will be understood that when a certain portion “includes” a certain component, the portion does not exclude another component but can further include another component, unless the context clearly dictates otherwise.

It is to be understood that the singular forms “a,” “an,” and “the” include plural referents unless the context clearly dictates otherwise.

An exterior material 10 for cooking appliance according to an embodiment of the disclosure may include: a base material 110; and a Silicon-Diamond like carbon (SiDLC) coating layer 120 provided on the base material 110, wherein the SiDLC coating layer 120 includes silicon (Si) of 1 weight % to 50 weight %, carbon (C), and other inevitable impurities.

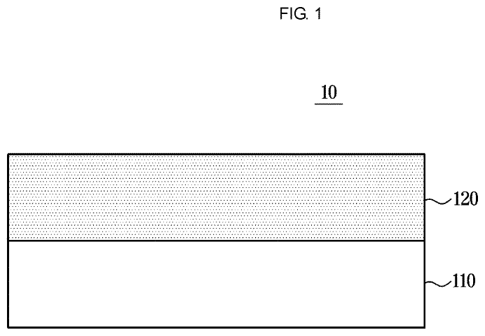

FIG. 1 is a schematic view showing an exterior material for cooking appliance according to an embodiment of the disclosure.

Referring to FIG. 1, the base material 110 may be provided in a lowest layer of the exterior material 10, and the SiDLC coating layer 120 may be formed on the base material 110. Accordingly, the SiDLC coating layer 120 may form an outermost surface of the exterior material 10.

The SiDLC coating layer 120 may include Si of 1 weight % to 50 weight %, C, and other inevitable impurities. Hereinafter, a reason of limiting values of component element contents in embodiments of the disclosure will be described. In the following description, a unit of weight % will be used unless the context clearly dictates otherwise.

A Si content may be 1 weight % to 50 weight %.

A low Si content may reduce strength of the exterior material 10 and an adhesion force between the base material 110 and the SiDLC coating layer 120, thereby resulting in deterioration of durability and scratch resistance. Accordingly, the Si content may be 1 weight % or more. However, a too great Si content may increase impurities of the SiDLC coating layer 120 in a manufacturing process, resulting in deterioration of durability, heat resistance, and scratch resistance. Accordingly, the Si content may be 50 weight % or less. Preferably, the Si content may be 10 weight % to 30 weight %.

The disclosure is characterized in that the SiDLC coating layer 120 including Si is formed directly on the base material 110 without forming a separate adhesive layer between the base material 110 and the SiDLC coating layer 120. Because the SiDLC coating layer 120 includes Si, detachment between the base material 110 and the SiDLC coating layer 120 may be prevented, and an adhesion force between the base material 110 and the SiDLC coating layer 120 may increase.

The remaining ingredient of the SiDLC coating layer 120 may be C. However, because unintended impurities may be inevitably mixed from a raw material or a surrounding environment in a general manufacturing process, such impurities may be not excluded. Because the impurities are already known to anyone of engineers involved in the general manufacturing process, details about the impurities will be not described in the present specification.

The base material 110 may include tempered glass such as ceramic glass to be prevented from being easily damaged. However, the base material 110 may be made of any other material.

Also, the base material 110 may have a thickness of 3 mm to 6 mm. A small thickness of the base material 110 may result in low durability, whereas a great thickness of the base material 110 may result in an increase of a raw material. Accordingly, the thickness of the base material 110 may be 3 mm to 6 mm, preferably, 4 mm to 6 mm, although not limited thereto.

The exterior material 10 according to an embodiment of the disclosure may improve durability by forming the SiDLC coating layer 120. Vickers hardness of the SiDLC coating layer 120 may be 1000 Hv to 2000 Hv.

Also, the exterior material 10 according to an embodiment of the disclosure may improve scratch resistance by forming the SiDLC coating layer 120.

Scratch resistance may be estimated through a variable load scratch test. The variable load scratch test may be performed based on an ASTM D7027, C1326, C1327 or C1624 scratch test standard.

By performing the variable load scratch test on the exterior material 10 according to an embodiment of the disclosure, a vertical force by which a scratch is generated on the SiDLC coating layer 120 was measured as 15 N to 20 N. The vertical force by which the scratch is generated is a vertical force measured at time at which the scratch is visible to the naked eye. The time at which the scratch is visible to the naked eye was estimated based on time at which a difference between brightness of an area where the scratch is generated and brightness of a background of the exterior material 10 is 3% or more.

Also, a friction coefficient of the SiDLC coating layer 120 may be 0.01 to 0.2.

The SiDLC coating layer 120 may secure a small friction coefficient by including Si and being manufactured at high temperature. Accordingly, by increasing slippability of the exterior material 10, cleaning performance may be improved. That is, the exterior material 10 according to an embodiment of the disclosure may implement a sanitary cooking environment by improving cleaning performance.

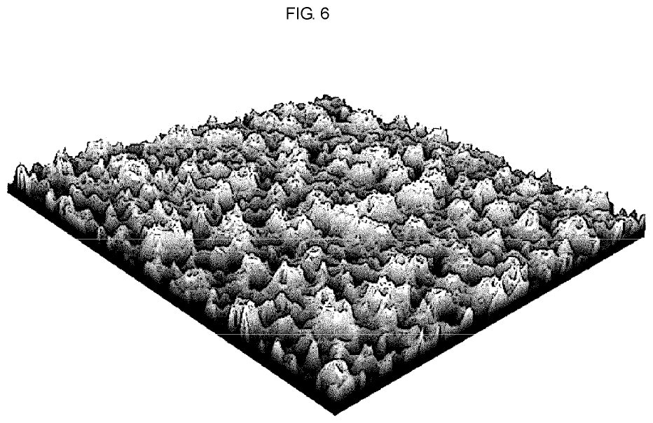

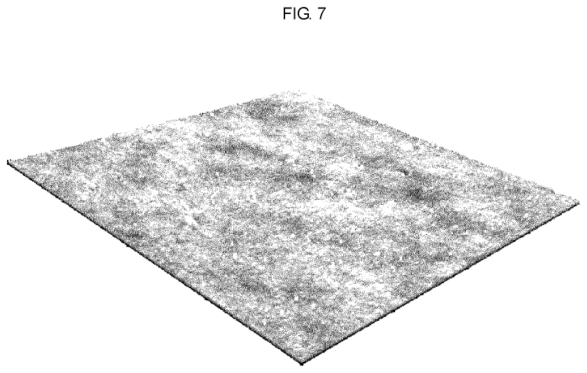

FIG. 6 is a picture obtained by photographing a surface of an exterior material for cooking appliance according to a comparative example through an Atomic Force Microscope (AFM), FIG. 7 is a picture obtained by photographing a surface of an exterior material for cooking appliance according to an embodiment of the disclosure through an AFM.

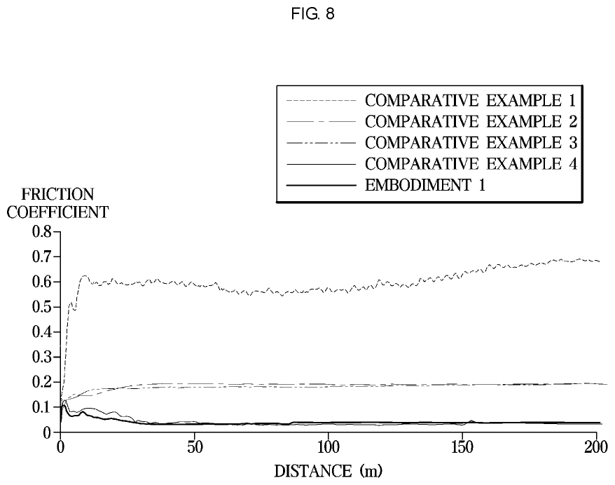

FIG. 8 is a graph showing friction coefficients of comparative examples and an embodiment.

It is seen from FIGS. 6 and 7 that a surface of the exterior material 10 according to an embodiment of the disclosure is much smoother than a surface of a comparative example.

Also, it is seen from FIG. 8 that, in a case in which the SiDLC coating layer 120 including Si is manufactured at high temperature, according to an embodiment of the disclosure, a low friction coefficient is secured.

Also, a chrominance value ΔE of the SiDLC coating layer 120 heated at 300° C. for 480 hours or more may be 1.0 or less.

Because a cooking appliance is subject to frequent heat entrance and exit, an exterior material for cooking appliance needs to have excellent heat resistance. The SiDLC coating layer 120 according to an embodiment of the disclosure may secure excellent heat resistance by being manufactured at high temperature.

Also, the SiDLC coating layer 120 may have a thickness of 1 μm to 4 μm. A small thickness of the SiDLC coating layer 120 may result in low Vickers hardness and low thermal resistance. Accordingly, the thickness of the SiDLC coating layer 120 may be 1 μm or more. However, a too great thickness of the SiDLC coating layer 120 may result in high manufacturing cost. Accordingly, the thickness of the SiDLC coating layer 120 may be 4 μm or less. Preferably, the thickness of the SiDLC coating layer 120 may be 1.5 μm to 3.5 μm, although not limited thereto.

Then, a method for manufacturing the exterior material 10, according to another aspect of the disclosure, will be described.

The method for manufacturing the exterior material 10, according to an embodiment of the disclosure, may include: preparing a base material 110; etching a surface of the base material 110; and forming a SiDLC coating layer 120 on the etched base material 110, wherein the forming of the SiDLC coating layer 120 may be performed at 100° C. to 400° C.

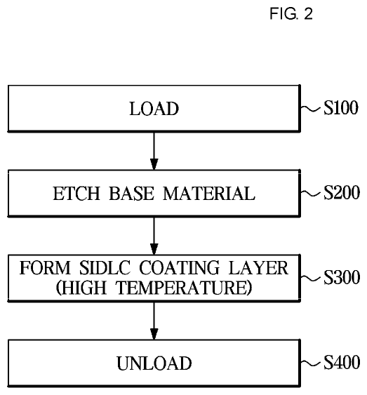

FIG. 2 is a schematic flowchart showing a method for manufacturing an exterior material for cooking appliance, according to an embodiment of the disclosure.

Referring to FIG. 2, the exterior material 10 according to an embodiment of the disclosure may be manufactured by a series of operations of loading a base material 110 on a substrate (S100), etching the base material 110 (S200), forming a SiDLC coating layer 120 (S300), and unloading the resultant structure (S400).

In operation S100, the base material 110 may be loaded on the substrate.

In operation S200, a surface of the base material 110 may be etched. The etching may be performed to arrange the surface of the base material 110 and activate the base material 110 before forming a coating layer 120. The etching may be performed through Linear Ion Source (LIS) treatment which will be described below. That is, the etching may be performed by spraying an ion gun onto the surface of the base material 110.

A linear ion source (LIS) process of spraying an ion beam onto the base material 110, which is a kind of a Physical Vapor Deposition (PVD) method, may be performed. The LIS process may be performed for about 120 minutes or less. The LIS process may be performed by injecting argon (Ar) of 10 to 50 standard cubic centimeters per minute (sccm) (cm³/min) into a chamber and applying a voltage of 1800±500 V to a substrate. Through the LIS process, an adhesion force of the coating layer 120 with respect to the base material 110 may be improved. Also, the SiDLC coating layer 120 may be formed by the LIS process.

More specifically, a voltage of 1800±500 V may be applied to the ion gun, and then the ion gun may be sprayed onto the substrate. The PVD method may have an advantage of high mass productivity, and a high-quality product may be manufactured through the LIS process.

In operation S300, the SiDLC coating layer 120 may be formed on the base material 110. SiDLC coating according to an embodiment of the disclosure may be performed by ion deposition. The ion deposition may be a method for ionizing a hydrocarbon gas by plasma discharge, and then acceleration-colliding the ions with a substrate to form a thin film. More specifically, by spaying an ion gun onto the base material 110, the SiDCL coating layer 120 may be coated on the base material 110. The hydrocarbon gas may include acetylene (C₂H₂), methane (CH₄), and benzene (C₆H₆), although not limited thereto. Operation of forming the SiDLC coating layer 120 may be performed for about 500 minutes or less.

Meanwhile, operation of forming the SiDLC coating layer 120 may be performed at 100° C. to 400° C.

In a case in which operation of forming the SiDLC coating layer 120 is performed at low processing temperature, adhesion stability between the base material 110 and the SiDLC coating layer 120 may deteriorate. Accordingly, operation of forming the SiDLC coating layer 120 may be performed at processing temperature of 100° C. or higher. However, in a case in which operation of forming the SiDLC coating layer 120 is performed at too high processing temperature, graphitizing may progress to increase a sp² binding content and decrease a spa binding content, which results in deterioration of binding stability. Accordingly, operation of forming the SiDLC coating layer 120 may be performed at processing temperature of 400° C. or lower.

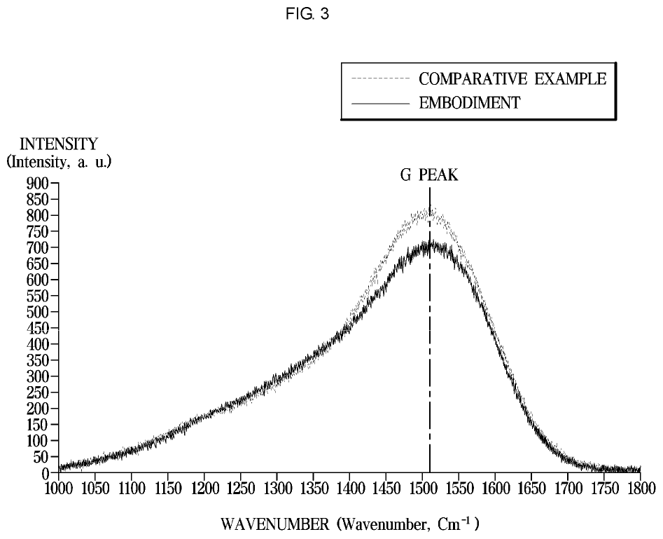

FIG. 3 is a graph showing changes of Raman spectrums according to manufacturing process temperature.

A Raman spectrum is a graph showing an arrangement of specific light that is generated by the Raman effect. The Raman effect is a phenomenon in which by irradiating strong light of a single wavelength to a transparent material to spectralize scattered light, a spectrum line of a slightly longer or shorter wavelength than incident light, as well as light having the same wavelength as the incident light, is observed. By analyzing a Raman spectrum, a molecular structure of a material may be inferred.

In a Raman spectrum, a G peak may represent a peak commonly found in graphite materials. The G peak may occur in a mode in which neighboring carbon atoms vibrate in opposite directions. In the disclosure, a G peak of a Raman spectrum means a peak occurring around a wavenumber of 1580 cm⁻¹.

Generally, a high sp³ binding content results in high thermal stability. A low G peak of a Raman spectrum may be interpreted as a high sp³ binding content and a low sp² binding content. It is seen from FIG. 3 that a G peak decreases according to an increase of processing temperature. Accordingly, it may be identified that the exterior material 10 including the SiDLC coating layer 120 subject to a high temperature process has more excellent thermal stability than a coating layer 120 subject to a low temperature process due to stabilization of the coating layer 120.

Also, the base material 110 may include ceramic glass, and have a thickness of 3 mm to 6 mm. Also, the SiDLC coating layer 120 may include Si of 1 weight % to 50 weight %, C, and other inevitable impurities, and have a thickness of 1 μm to 4 μm.

Details about a kind and thickness of the base material 110 and a component system and thickness of the SiDLC coating layer 120 have been described above.

Hereinafter, a cooking appliance according to another aspect of the disclosure will be described.

The cooking appliance according to an embodiment of the disclosure may include: a cooking appliance body; and an exterior material provided on an outer side of the cooking appliance body, wherein the exterior material includes: a base material 110; and a SiDLC coating layer 120 provided on the base material 110, wherein the SiDLC coating layer 120 includes Si of 1 weight % to 50 weight %, C, and other inevitable impurities.

Details about the exterior material 10 have been described above.

Various components constructing the cooking appliance may be installed in the cooking appliance body. Also, the cooking appliance body may provide a user interface for receiving a control command from a user and displaying operation information of the cooking appliance for the user. The user interface may include a flat panel display, and use a LCD or LED.

Hereinafter, the disclosure will be described in more detail through an embodiment. However, the embodiment is provided for illustration purpose only and not for the purpose of limiting the disclosure. The scope of right of the disclosure is decided by content written in the claims and content reasonably inferred from the claims.

After cooking appliance exterior material test pieces of about 600*520 mm, having Si contents, manufacturing process temperature, and thicknesses of SiDLC coating layer 120s, as shown in Table 1, are prepared, a Vickers hardness test, a variable load scratch test, a blue scrubber scratch test, a friction coefficient measurement test, and a heat resistance test were performed.

TABLE 1

| | Si | Manufacturing | Thickness of |
|---|---|---|---|
| | Content | Process | SiDLC Coating |
| | (Weight | Temperature | Layer |
| Classification | %) | (° C.) | (μm) |
| Embodiment 1 | 15 | 200 | 2.2 |
| Embodiment 2 | 10 | 100 | 1.5 |
| Embodiment 3 | 30 | 350 | 3.0 |
| Comparative | 0 | 600 | 0 |
| Example 1 | | | |
| Comparative | 0 | 25 | 1.3 |
| Example 2 | | | |
| Comparative | 15 | 25 | 1.34 |
| Example 3 | | | |
| Comparative | 0 | 200 | 0.92 |
| Example 4 | | | |
| Comparative | 15 | 200 | 0.95 |
| Example 5 | | | |
| Comparative | 0 | 200 | 1.81 |
| Example 6 | | | |
| Comparative | 55 | 200 | 2.2 |
| Example 7 | | | |

Results of the Vickers hardness test, the variable load scratch test, the blue scrubber scratch test, the friction coefficient measurement test, and the heat resistance test are shown in Table 2, below.

The Vickers hardness was measured by pressing the test pieces with pyramid-shaped particles having diamond quadrangular pyramids and measuring diagonal lines of pyramid-shaped concave portions made in the test pieces to thereby obtain hardness.

The variable load scratch test was performed by a method of applying a vertical force to the test pieces through a diamond indenter (Rockwell C cone) and observing scratch generation behaviors generated on surfaces of the test pieces. At this time, by increasing the vertical force applied to the test pieces gradually from 0.5 N to 20 N while moving the test pieces at speed of 240 mm/s, the scratch generation behaviors were observed through an optical microscope or an electron microscope.

A vertical force by which a scratch is generated is a vertical force measured at time at which the scratch is visible to the naked eye. The time at which the scratch is visible to the naked eye was based on time at which a difference between brightness of an area where the scratch is generated and brightness of a background of the exterior material 10 is 3%.

The blue scrubber scratch test was performed by a method of measuring a scratch distribution generated by causing friction 100 times with a constant force of 3 kgf. The blue scrubber scratch test was performed by applying a relatively greater force than in the variable load scratch test, and it is meaningful that the blue scrubber scratch test was performed under a condition that is more similar to an environment of a cooking appliance in actual use than that of the variable load scratch test. Meanwhile, Table 2 shows generation distributions of scratches having grooves of 1 μm.

The friction coefficient measurement test was performed by a method of putting the test pieces on a table positioned horizontally, applying a horizontal force to the test pieces, and calculating friction coefficients, based on a ISO 8295 test method.

The heat resistance test was performed by performing 20 cycles of which each cycle is continuous heating at 300° C. for 24 hours, and then measuring a chrominance value ΔE which is a difference between a color value before heating and a color value after heating.

TABLE 2

| | | | Blue | | |
|---|---|---|---|---|---|
| | | Variable | Scrubber | | |
| | Vickers | Load | Scratch | | |
| | Hard- | Scratch | Test | Friction | Chromi- |
| | ness | Test | (Pieces/ | Co- | nance |
| Classification | (Hv) | (N) | 20 mm²) | efficient | Value |
| Embodiment | 1193 | 18 | 0 | 0.04 | 0.15 |
| 1 | | | | | |
| Embodiment | 1180 | 16 | 3 | 0.06 | 0.21 |
| 2 | | | | | |
| Embodiment | 1150 | 19 | 1 | 0.05 | 0.07 |
| 3 | | | | | |
| Comparative | 856 | 12 | 15 | 0.62 | 1.58 |
| Example 1 | | | | | |
| Comparative | 890 | 11 | 42 | 0.14 | 1.07 |
| Example 2 | | | | | |
| Comparative | 890 | 16 | 38 | 0.06 | 1.01 |
| Example 3 | | | | | |
| Comparative | 938 | 10 | 25 | 0.19 | 1.43 |
| Example 4 | | | | | |
| Comparative | 952 | 17 | 0 | 0.04 | 1.31 |
| Example 5 | | | | | |
| Comparative | 1008 | 11 | 31 | 0.18 | 0.82 |
| Example 6 | | | | | |
| Comparative | 820 | 13 | 45 | 0.08 | 0.51 |
| Example 7 | | | | | |

Referring to Table 2, because embodiments 1 to 3 satisfy all of a Si content, manufacturing process temperature, and a thickness of a SiDLC coating layer 120, proposed in the disclosure, the embodiments 1 to 3 satisfied Vickers hardness of 1000 Hv to 2000 Hv, a vertical force of 15 N to 20 N by which a scratch is generated, a friction coefficient of 0.01 to 0.2, and a chrominance value ΔE of 1.0 or less. That is, it may be evaluated that all of durability, heat resistance, scratch resistance, and cleaning performance are excellent.

However, because comparative examples 1, 2, 4, and 6 do not contain Si, the comparative examples 1, 2, 4, and 6 showed low Vickers hardness, low scratch resistance, and small friction coefficients.

Also, because comparative example 7 has a Si content exceeding 50 weight %, the comparative example 7 showed low Vickers hardness, low scratch resistance, a small low friction coefficient, and low heat resistance due to a large amount of impurities contained in SiDLC coating layers 120.

Also, because comparative examples 2 and 3 do not satisfy manufacturing process temperature of 100° C. to 400° C., the comparative examples 2 and 3 showed low Vickers hardness, low scratch resistance, small friction coefficients, and low heat resistance.

Also, because comparative example 5 has a small thickness of a SiDLC coating layer 120, the comparative example 5 showed low Vickers hardness, low scratch resistance, a small friction coefficient, and low heat resistance.

According to an embodiment of the disclosure, there are provided an exterior material for cooking appliance capable of improving durability, heat resistance, scratch resistance, and cleaning performance by forming a SiDLC coating layer 120 including silicon under a high-temperature environment, and a method for manufacturing the exterior material 10.

However, effects that can be achieved by the exterior material 10 according to an embodiment of the disclosure are not limited to the above-mentioned those, and other effects not mentioned may be clearly understood by one of ordinary skill in the technical art to which the disclosure belongs from the above descriptions.

Although a few embodiments of the disclosure have been shown and described, it would be appreciated by those skilled in the art that changes may be made in these embodiments without departing from the principles and spirit of the disclosure, the scope of which is defined in the claims and their equivalents.

What is claimed is:

1. An exterior material for a cooking appliance, comprising:
a base material; and
a Silicon-Diamond like carbon (SiDLC) coating layer provided on the base material,
wherein the SiDLC coating layer comprises Silicon (Si) of about 1 weight % to 50 weight %, carbon (C), and other inevitable impurities.

2. The cooking appliance exterior material of claim 1, wherein the base material comprises ceramic glass.

3. The cooking appliance exterior material of claim 1, wherein a thickness of the base material is about 3 mm to 6 mm.

4. The cooking appliance exterior material of claim 1, wherein Vickers hardness of the SiDLC coating layer is about 1000 Hv to 2000 Hv.

5. The cooking appliance exterior material of claim 1, wherein a vertical force by which a scratch is generated on the SiDLC coating layer is about 15N to 20N.

6. The cooking appliance exterior material of claim 1, wherein a friction coefficient of the SiDLC coating layer is about 0.01 to 0.2.

7. The cooking appliance exterior material of claim 1, wherein a chrominance value ΔE, of the SiDLC coating layer heated at about 300° C. for 480 hours or more, is about 1.0 or less.

8. The cooking appliance exterior material of claim 1, wherein a thickness of the SiDLC coating layer is about 1 μm to 4 μm.

9. A method for manufacturing a cooking appliance exterior material, comprising:
preparing a base material;
etching a surface of the base material; and
forming a Silicon-Diamond like carbon (SiDLC) coating layer on the etched base material,
wherein the forming of the SiDLC coating layer is performed at about 100° C. to 400° C.

10. The method of claim 9, wherein the etching of the surface of the base material comprises performing Linear Ion Source (LIS) treatment to etch the surface of the base material.

11. The method of claim 9, wherein the forming of the SiDLC coating layer comprises performing the SiDLC coating layer using a Physical Vapor Deposition (PVD) method.

12. The method of claim 11, wherein the PVD method comprises a Linear Ion Source (LIS) method.

13. The method of claim 9, wherein the base material comprises ceramic glass.

14. The method of claim 9, wherein a thickness of the base material is about 3 mm to 6 mm.

15. The method of claim 9, wherein the SiDLC coating layer comprises Silicon (Si) of about 1 weight % to 50 weight %, carbon (C), and other inevitable impurities.

16. The method of claim 9, wherein a thickness of the SiDLC coating layer is about 1 μm to 4 μm.

17. A cooking appliance, comprising:
a cooking appliance body; and
an exterior material provided on an outer side of the cooking appliance body,
wherein the exterior material includes:
a base material; and
a Silicon-Diamond like carbon (SiDLC) coating layer provided on the base material, the SiDLC coating layer including silicon (Si) of about 1 weight % to 50 weight %, carbon (C), and other inevitable impurities.

18. The cooking appliance according to claim 17, wherein Vickers hardness of the SiDLC coating layer is about 1000 Hv to 2000 Hv.

19. The cooking appliance according to claim 17, a chrominance value ΔE, of the SiDLC coating layer heated at about 300° C. for 480 hours or more, is about 1.0 or less.

20. The cooking appliance according to claim 17, a thickness of the SiDLC coating layer is about 1 μm to 4 μm.
